(19) United States
(12) Patent Application Publication
(10) Pub. No.: US 2025/0306142 A1
(43) Pub. Date: Oct. 2, 2025

(54) DEVICE FOR DETERMINING A MAGNETIC FIELD OF INTEREST AT A MEASUREMENT LOCATION

(71) Applicant: Robert Bosch GmbH, Stuttgart (DE)

(72) Inventor: Tino Fuchs, Tuebingen (DE)

(21) Appl. No.: 19/081,288

(22) Filed: Mar. 17, 2025

(30) Foreign Application Priority Data
Mar. 27, 2024 (DE) 10 2024 202 903.3

(51) Int. Cl. G01R 33/26

(52) U.S. Cl. CPC G01R 33/26

(57) ABSTRACT

A device for determining a magnetic field of interest at a measurement location. The device includes first and second sensor crystals having color centers, the first sensor crystal being arranged at the measurement location, and the second being arranged at a distance therefrom. An excitation light generator generates a pulsed excitation light which irradiates the first and second sensor crystals. A field generator generates a magnetic field. The first and the second sensor crystal are arranged in the magnetic field. A measuring arrangement detects a fluorescent light emanating from the first and the second sensor crystal. The device applies the same magnetic field and excitation light to the first and second sensor crystals and directly measures the difference between the magnetic fields at the respective locations of the first and second sensor crystals to suppress a temporally variable but spatially homogeneous background magnetic field at the measurement location.

### FIELD

The present invention relates to a device for determining a magnetic field of interest at a measurement location.

### BACKGROUND INFORMATION

In particular quantum-based or optically pumped magnetometers are suitable as sensors for measuring very small magnetic field strengths. Such magnetometers often use optically pumped and optically detected magnetic resonances (ODMR). This takes advantage of the fact that under the influence of an external magnetic field, the energy levels of certain spin states of unpaired electrons split, the so-called Zeeman effect. The splitting of the energy levels results in altered transitions during relaxation from excited states, which can then be measured, for example, by optical excitation and frequency-dependent detection of the resulting fluorescence radiation, or by observing optical properties such as the absorption of light. The measured optical parameters can then be used to infer the magnetic field strength.

Sensor crystals having excitable defect centers (so-called color centers) can be used for such quantum-based magnetic field sensors. Typically, diamonds that are homogeneously doped with negative nitrogen vacancy centers (NV centers) are used. The quantum state is prepared by optical excitation and interaction with a static magnetic field and a dynamic magnetic field, i.e., a microwave field.

For measuring very small magnetic field strengths, quantum-based magnetic sensors based on nitrogen vacancy centers are described, for example, in German Patent Application No. DE 10 2018 220 234 A1, DE 10 2018 214 617 A1 or DE 10 2020 214 278 A1. The information stored in the spin system is optically read out by detecting the fluorescence rates of the NV center, which are dependent on the spin state. Therefore, the accuracy is limited, among other things, by the signal-to-noise ratio of the optical readout method of the NV center.

The optically detected measurement of magnetic resonances at NV centers in diamond is very suitable for measuring magnetic fields over a wide value range from pT to T by utilizing the Zeeman effect. One advantage of using ensembles of NV centers in diamond is the ability to achieve detection limits of less than 10 pT/√Hz and the detection of all components of the vector of the magnetic flux density B. An existing obstacle in the application of such sensitive NV magnetometers is the fact that under normal conditions at the intended site of use, there is magnetic noise, caused by electrical infrastructure, with root mean square values (rms values) of several hundred pT. In order, for example, to be able to measure a useful signal, such as the magnetic field generated by contraction of cardiac muscle, effective and efficient methods of noise suppression must be used. For example, a magnetic shield can be placed around the sensor and signal source. This shield, made of so-called mu-metal, is very expensive, heavy and severely limits the possible measurements, since, for example, no measurement is possible while the subject being examined is moving. An alternative method is to use a plurality of sensors to suppress ambient noise. This takes advantage of the fact that magnetic fields rapidly decrease in strength with increasing distance from the source, approximately inversely proportionally to the cube of the distance. The interfering background magnetic fields, on the other hand, usually have a negligible gradient. In the simplest case, if a system is built from two sensors, wherein one of them is placed as close as possible to the signal source, e.g. the thorax (sensor 1), and the other is placed at a greater distance of approximately 5 to 10 cm (sensor 2), then the result is a 2-point gradiometer. If the difference between the signals from sensor 1 and sensor 2 is calculated, a so-called “common mode rejection” is obtained, i.e., correlated signals are eliminated, and only the signal from sensor 1, which is caused by the source, is virtually filtered out. However, the application of this technology quickly reaches its limits when two autonomous sensors that each have their own individual signal evaluation are used, since the necessary, strictly required synchronicity of the signals is then lost, so that only moderate results in terms of the suppression of ambient noise are possible.

### SUMMARY

According to the present invention, a device for determining a magnetic field of interest at a measurement location is provided. Advantageous example embodiment of the present invention are disclosed herein.

The present invention presented here overcomes the problem of limited synchronicity of the sensor signals when a gradiometer is used to suppress ambient noise. The present invention uses a step of measuring two magnetic fields absolutely synchronously and under the same measuring conditions by means of an arrangement of two sensor crystals to provide the gradiometer. The result of the measurement is the difference between the phases accumulated by both on the Bloch sphere, which corresponds exactly to the difference between the magnetic fields experienced by the two sensor crystals during the phase accumulation time, which is denoted below as AB. This leads to an ideal common mode rejection, and thus to an effective and efficient suppression of the ambient noise acting on the two sensor crystals.

In detail, according to an example embodiment of the present invention, the device for determining a magnetic field of interest at a measurement location comprises a first and a second sensor crystal having color centers, wherein the first sensor crystal is arranged at the measurement location, and the second sensor crystal is arranged at a distance from the measurement location; an excitation light generating means for generating a pulsed excitation light which irradiates the first and the second sensor crystal; a field generating means for generating a magnetic field, wherein the first and the second sensor crystal are arranged in the magnetic field; and a measuring means for detecting a fluorescent light emanating from the first and the second sensor crystal. The device is configured to apply the same magnetic field and the same excitation light to the first and the second sensor crystal, and to directly measure the difference between the magnetic fields at the location of the first sensor crystal and at the location of the second sensor crystal. This difference can be determined as the magnetic field of interest at the measurement location, or, with a known distance r between the first and the second sensor crystal, the gradient of the magnetic field at the measurement location can be determined as OB/dr.

By measuring the difference between the magnetic fields at the location of the first sensor crystal and at the location of the second sensor crystal, a temporally variable but spatially homogeneous background magnetic field at the measurement location can be suppressed in the measurement in order to improve the signal-to-noise ratio for the measurement of a useful signal with a non-vanishing gradient at the measurement location.

In one example embodiment of the present invention, the device is configured to measure the difference between the magnetic fields at the location of the first sensor crystal and at the location of the second sensor crystal by means of a pulsed ODMR measurement.

An advantageously usable measurement method is based on quantum mechanical superposition states. A typical protocol here is, for example, free induction decay (FID, also called Ramsey protocol) or the Hahn echo. A microwave pulse is used to create a quantum mechanical superposition state, which is freely developed for an evolution time. The state oscillates at the natural frequency (Lamor frequency) around an existing magnetic field, and the phase between this oscillation and the microwave, which provides information about the magnetic field, is measured at the end.

A typical microwave pulse sequence (FID) is

$$\frac{π}{2} - τ - \frac{π}{2} .$$

A laser pulse first initializes a spin state |m=0>. The first

$$\frac{π}{2} -$$

pulse prepares the superposition state 1/√2 (|m=0>+|m=±1>). This is followed by a temporal development τ in which a phase difference due to the frequency difference between the Lamor precession and the microwave is picked up. This phase difference is then transferred with the last

$$\frac{π}{2} -$$

pulse into a population difference, which can then be read out.

In one example embodiment of the present invention, the device is configured to determine the magnetic field of interest at the measurement location as the difference between the values at the location of the first crystal and at the location of the second crystal.

In one example embodiment of the present invention, the device is configured to direct excitation light generated by the excitation light generating means equally onto the first and the second sensor crystal by means of a beam splitter. Identical excitation and readout conditions can thus be achieved in a simple manner.

In one example embodiment of the present invention, the device is configured to generate an alternating electrical signal, which is applied to a first coil arrangement and to a second coil arrangement, wherein the first coil arrangement generates a first magnetic field at the location of the first sensor crystal, and the second coil arrangement generates a second magnetic field at the location of the second sensor crystal, wherein the strength and temporal profile of the first and the second magnetic field are identical. Identical spin conditions can thus be achieved in a simple manner.

In one example embodiment of the present invention, the first and the second magnetic field comprise magnetic field pulses. The magnetic field pulses are pulses of an alternating magnetic field. Typical frequency values of such alternating fields used to excite spin-based quantum systems are in the high-frequency range. The abbreviation “HF” for the term “high frequency” is also used below. The frequency of the high frequency (HF) field depends on the quantum system to be excited, i.e., on the energy difference (which corresponds to a frequency) between the quantum mechanical states of the quantum system between which transitions are to be effected. Typical frequencies can be in the microwave range, e.g. between 300 MHz and 300 GHz or between 300 MHz and 1 THz. The quantum system can be, for example, an NV center in a diamond, wherein the ground state is a triplet in which (without an external magnetic field) there is an energy difference corresponding to 2.87 GHz between spin equal to 0 (|m=0>) and spin equal to +1 or −1 (|m=±1>).

In one example embodiment of the present invention, the sensor crystal having color centers is a diamond crystal having nitrogen vacancy centers. These can be produced very reliably with the desired parameters.

In example embodiments of the present invention, the magnetic field of interest at a measurement location can be the magnetic field generated by contraction of a muscle, such as in particular cardiac muscle. Magnetocardiograms are thus very easy to obtain.

Further advantages and embodiments of the present invention can be found in the description and the figures.

The present invention is shown schematically in the figures on the basis of exemplary embodiments and is described below with reference to the figures.

### BRIEF DESCRIPTION OF THE DRAWINGS

FIG. 1 shows an embodiment of a magnetometer according to an example embodiment of the present invention.

FIG. 2 shows a measurement scheme according to a Ramsey measurement, as can be used in the context of the present invention.

### DETAILED DESCRIPTION OF EXAMPLE EMBODIMENTS

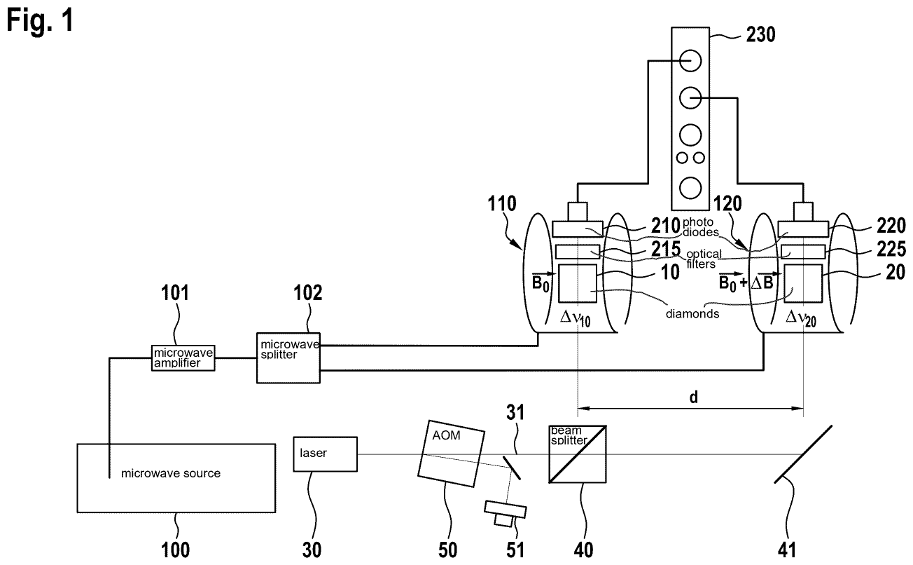

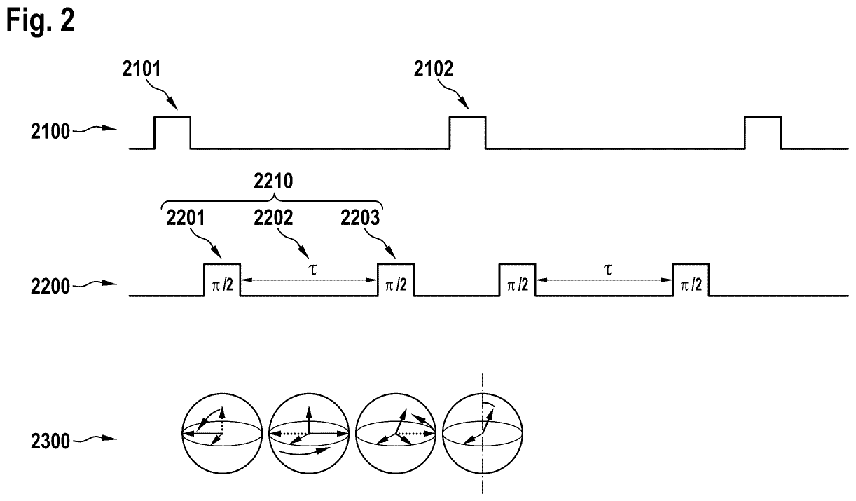

FIG. 1 shows an embodiment of a magnetometer according to an embodiment of the present invention. An exemplary measurement process is illustrated in FIG. 2, which shows a profile 2100 of an excitation or readout light (beam 31 in FIG. 1) and a profile 2200 of a microwave field. The figures are described in a coherent and comprehensive manner below.

Pulsed ODMR experiments, such as a so-called Ramsey measurement, conventionally comprise an initial light pulse (in particular laser pulse) 2101 for spin polarization (in particular in the state |m=0>), a magnetic field pulse sequence 2210 for spin manipulation, and a light pulse (in particular laser pulse) 2102 for spin readout via the fluorescence intensity (readout pulse).

The embodiment shown in FIG. 1 has two diamonds 10 and 20 at a distance d suitable for the measurement, usually a few centimeters, wherein the distance must be adjusted according to the specific measuring task. For example, the two diamonds 10, 20 have negatively charged NV centers with concentrations in the range of approximately 1 ppm and P1 concentrations (nitrogen centers) below 10 ppm. The two diamonds should have the same properties in this regard and, for example, originate from the same production batch.

For the purpose of optical pumping and optical readout during the measurement protocol, the two diamonds 10, 20 are irradiated with green light, e.g. 532 nm, by a laser 30, wherein the light 31 of the laser is divided into approximately equal parts between the two diamonds by a beam splitter 40 in the form of, for example, a prism splitter, wherein further deflection elements 41, etc., can be used if necessary.

To apply a Ramsey sequence, as illustrated for example in FIG. 2, the light must be pulsed (see signal 2100 in said figure). For this purpose, an acousto-optical modulator, AOM, 50 can be used, as shown in the figure. A reference intensity measurement can be carried out using a photodiode 51.

Before the start of the Ramsey sequence, the laser beam 31 is switched through from the AOM 50 toward the diamonds 10, 20 for a duration of a few to several hundred microseconds. As a result, the spins of the NV centers are initialized in the two diamonds, wherein e.g. >80% of the NV centers are in a spin state |mₛ=0> (“bright state”) as a result. This corresponds to the light pulse 2101 in FIG. 2.

Subsequently (e.g. a few microseconds later), the two diamonds are simultaneously exposed to a microwave field at a frequency of approximately 2.87 GHz such that they experience a π/2 pulse in the image of the Bloch sphere, i.e., they are brought into a symmetric coherent superposition state 1/√2 (|m=0>+|m=±1>) of “bright state” and “dark state” | ms=±1>. This corresponds to the magnetic field pulse 2201 in FIG. 2.

For this purpose, the microwave field should be very homogeneous in the previously illuminated part of the diamond, as far as possible better than 99% homogeneous, so that as far as possible all the NV centers present therein are converted into this state. A Helmholtz arrangement 110, 120 of two coil windings, as shown in FIG. 1, can be used for this purpose, wherein the Helmholtz arrangements of the two diamonds are fed jointly by one microwave source 100, which ensures the required synchronicity. A microwave splitter 102 ensures the symmetrical distribution of the microwave power. In order to achieve sufficiently high Rabi frequencies, which are proportional to the magnetic field strength of the microwave field in the diamond, a microwave amplifier 101 can be used.

After the π/2 pulse has been applied synchronously to the two diamonds, the phase accumulation period of the length t begins. In the image of the Bloch sphere in the rotating frame approximation, this means that the coherent superposition state executes a rotation in the equatorial plane, wherein the angle of the rotation corresponds to the time integral between 0 and t of the product of detuning Δν and time t′. This corresponds to the period 2202 in FIG. 2.

In this case, the detuning Δν is the frequency difference between the frequency of the applied microwave field ν_{MW} and the resonance frequency ν_{0→1} at the transition from bright state |0> to dark state |±1>.

$$Δ v = {v}_{0 \to 1} - {v}_{MW}$$

Since the frequency ν_{MW} of the applied microwave field is exactly the same for the two diamonds, a difference in the phase accumulation between the two diamonds during the duration τ can only result from the fact that the frequency at the transition |0>→|±1> is different, i.e., ν_{0→1,10}≠ν_{0→1,20 or} Δν₁₀≠Δν₂₀, wherein the indices 10 and 20 denote sizes for the two different diamonds 10 and 20, respectively. This frequency is determined by the Zeeman effect by means of the effective magnetic field. This means that, if the magnetic field of the two diamonds differs by AB, then a correspondingly different phase position results after the accumulation period τ.

In the present case, the measured phase difference is utilized to determine ΔB. The phase difference can be measured according to the Ramsey protocol after t has elapsed, by applying a second π/2 pulse. This corresponds to the magnetic field pulse 2203 in FIG. 2.

If the detuning were exactly zero, this π/2 pulse would convert the state exactly into the bright state. The phase accumulated by finite detuning during t determines the probability P_{|±1>} for the occurrence of the dark state via a dependence of the form cos² (Δϕ/2). For this, the following applies:

$${P}_{\vert \pm 1 > , 10} ( t ) = {cos}^{2} ( \frac{{\int }_{0}^{τ} ( Δ {v}_{10} \cdot {t}^{′} ) {dt}^{′}}{2} )$$

$${P}_{\vert \pm 1 > , 20} ( t ) = {cos}^{2} ( \frac{{\int }_{0}^{τ} ( Δ {v}_{20} \cdot {t}^{′} ) {dt}^{′}}{2} )$$

By measuring the probability P_{|±1>}, it is possible to precisely deduce Δϕ and thus Δν and thus, with differential evaluation of the two diamonds, ΔB.

The probability P_{|±1>} can be measured via a readout light pulse after the second π/2 pulse, analogously to the excitation pulse or pump pulse before the first π/2 pulse. This corresponds to the light pulse 2102 in FIG. 2.

A photodiode 210, 220 is provided for the measurement. Between each diamond 10, 20 and photodiode 210, 220 there is an optical filter 215, 225, which blocks green excitation light on the way to the detector and only allows fluorescent light from the NV centers at wavelengths >˜650 nm to pass through. The intensity of the fluorescent light measured at each of the two diamonds 10, 20 as the sum of the individual contributions of all NV centers agrees as an ensemble mean value with the probability P_{|±1>} for the individual NV center. From the difference in the photocurrent measured on the photodiodes of the two diamonds during this readout pulse or the temporal integration of the photocurrent, ΔB is determined, wherein the relationship

$$Δ {v}_{10} - Δ {v}_{20} = γ \cdot Δ B$$

is used, where γ: gyromagnetic ratio of the NV centers.

All magnetic field effects B from the noisy environment that affected the two diamonds to same extent during t are thereby eliminated. The usable time t is determined by the spin decoherence time of the NV centers and is approximately 1-100 μs for the best diamonds currently available. If the required bandwidth for measuring ΔB is at lower frequencies, such as 200 Hz in the case of typical magnetocardiogram measurements, the presented sequence can then be repeated several hundred times, as a result of which the accuracy of the result is improved by a factor of √n, where n is the number of repetitions, by averaging the measured differences of the detectors in the readout phase.

1-9. (canceled)

10. A device for determining a magnetic field of interest at a measurement location, comprising:
a first sensor crystal and a second sensor crystal having color centers, wherein the first sensor crystal is arranged at the measurement location, and the second sensor crystal is arranged at a distance from the measurement location,
an excitation light generator configured to generate a pulsed excitation light which irradiates the first sensor crystal and the second sensor crystal;
a field generator configured to generate a magnetic field, wherein the first and the second sensor crystal are arranged in the magnetic field; and
a measuring arrangement configured to detect a fluorescent light emanating from the first and the second sensor crystals;
wherein the device is configured to apply the same magnetic field and the same excitation light to the first and the second sensor crystal;
wherein the device is configured to directly measure a difference between the magnetic fields at the location of the first sensor crystal and at the location of the second sensor crystal.

11. The device according to claim 10, which is configured to measure the difference between the magnetic fields at the location of the first sensor crystal and at the location of the second sensor crystal using a pulsed ODMR measurement.

12. The device according to claim 10, wherein the device is configured to measure the difference between the magnetic fields at the location of the first sensor crystal and at the location of the second sensor crystal using a Ramsey measurement.

13. The device according to claim 10, wherein the device is configured to direct excitation light generated by the excitation light generator equally onto the first and the second sensor crystal using a beam splitter.

14. The device according to claim 10, wherein the field generator is configured to generate an alternating electrical signal, which is applied to a first coil arrangement and to a second coil arrangement, wherein the first coil arrangement generates a first magnetic field at the location of the first sensor crystal, and the second coil arrangement generates a second magnetic field at the location of the second sensor crystal, wherein a strength and temporal profile of the first and the second magnetic field are identical.

15. The device according to claim 10, wherein the first and second sensor crystal having color centers are diamond crystals having nitrogen vacancy centers.

16. The device according to claim 10, wherein the device is configured to measure the difference between the magnetic fields at the location of the first sensor crystal and at the location of the second sensor crystal as the magnetic field of interest.

17. The device according to claim 10, wherein the device is configured to measure a local gradient of the difference between the magnetic fields at the location of the first sensor crystal and at the location of the second sensor crystal as the magnetic field of interest.

18. The device according to claim 10, wherein the device is configured o measure the magnetic field that is created during contraction of a cardiac muscle, as the magnetic field of interest.
